(19) United States
(12) Patent Application Publication
(10) Pub. No.: US 2015/0059820 A1
(43) Pub. Date: Mar. 5, 2015

(54) SEMICONDUCTOR ELEMENT FOR A THERMOELECTRIC MODULE, AND THERMOELECTRIC MODULE

(71) Applicant: EMITEC GESELLSCHAFT FUER EMISSIONSTECHNOLOGIE MBH, LOHMAR (DE)

(72) Inventors: ROLF BRUECK, BERGISCH GLADBACH (DE); SIGRID LIMBECK, MUCH (DE)

(21) Appl. No.: 14/535,507

(22) Filed: Nov. 7, 2014

Related U.S. Application Data
(63) Continuation of application No. PCT/EP2013/057755, filed on Apr. 15, 2013.

(30) Foreign Application Priority Data
May 7, 2012 (DE) 102012103968.2

(51) Int. Cl. H01L 35/32

(52) U.S. Cl. CPC H01L 35/32
USPC 136/230

(57) ABSTRACT

A semiconductor element includes at least a thermoelectric material and a first frame part which are connected to each other in a force-locking manner. The first frame part forms an electrical conductor and is made of a ferritic steel which, in particular, has good thermal conductivity and low thermal expansion in addition to good electrical conductivity. A thermoelectric module having semiconductor elements is also provided.

### CROSS-REFERENCE TO RELATED APPLICATION

This is a continuation, under 35 U.S.C. §120, of copending International Application No. PCT/EP2013/057755, filed Apr. 15, 2013, which designated the United States; this application also claims the priority, under 35 U.S.C. §119, of German Patent Application DE 10 2002 103 968.2, filed May 7, 2012; the prior applications are herewith incorporated by reference in their entirety.

### BACKGROUND OF THE INVENTION

### Field of the Invention

The present invention relates to a semiconductor element and to a thermoelectric module.

The exhaust gas from an internal combustion engine of a motor vehicle has thermal energy, which can be converted into electrical energy by using a thermoelectric generator, for example to fill a battery or some other energy storage device and/or to feed the required energy directly to electrical loads. The motor vehicle is thus operated with a better energy efficiency, and energy is available to a greater extent for the operation of the motor vehicle.

Such a thermoelectric generator has at least one thermoelectric module. Thermoelectric modules include e.g. at least two semiconductor elements (p-doped and n-doped) which are alternately provided with electrically conductive bridges on their top side and underside (towards the respective hot side and cold side) and which form the smallest thermoelectric unit or thermoelectric element. Thermoelectric materials are of such a type that they can effectively convert thermal energy into electrical energy (Seebeck effect), and vice-versa (Peltier effect). If a temperature gradient is provided on the two sides of the semiconductor elements, then a voltage potential forms between the ends of the semiconductor elements. The charge carriers on the hotter side are excited into the conduction band to an increased extent by the higher temperature. As a result of the concentration difference produced in that case in the conduction band, charge carriers diffuse to the colder side of the semiconductor element, as a result of which the potential difference arises. Preferably, numerous semiconductor elements are electrically connected in series in a thermoelectric module. In order to ensure that the generated potential differences of the semiconductor elements in series do not mutually cancel one another out, semiconductor elements having different majority charge carriers (n-doped and p-doped) are always alternately brought into direct electrical contact. The electric circuit can be closed and electrical power can thus be tapped off through the use of a connected load resistor.

In order to ensure permanent usability of the semiconductor elements, a diffusion barrier is regularly disposed between the electrically conductive bridges and the thermoelectric material. The diffusion barrier prevents material contained in the electrical bridges from diffusing into the thermoelectric material, and thus prevents a loss of efficacy or functional failure of the semiconductor material or of the thermoelectric element. The thermoelectric modules or the semiconductor elements are usually constructed by assembling the individual components of thermoelectric material, diffusion barrier, electrically conductive bridges, insulation and, if appropriate, further housing elements to form a thermoelectric module over which a hot and a cold medium respectively flow. The assembly of numerous individual components also requires precise tuning of the individual component tolerances and taking into account the heat transfers from the hot side to the cold side and that sufficient contact be made with the electrically conductive bridges, in such a way that a current flow through the thermoelectric module can be generated. The cost factor is an important parameter precisely with regard to providing thermoelectric generators in motor vehicles and with regard to the numbers prevailing there. A major portion of the costs is caused by the materials used for constructing a thermoelectric generator, which are very expensive in some instances.

### SUMMARY OF THE INVENTION

It is accordingly an object of the invention to provide a semiconductor element for a thermoelectric module and a thermoelectric module, which overcome the hereinafore-mentioned disadvantages and at least partly solve the highlighted problems of the heretofore-known elements and modules of this general type. In particular, the intention is to specify a semiconductor element which is suitable for diverse cases of use, which has an improved resistance to loads arising during thermal cycling, and which enables a thermoelectric module to be constructed as simply and cost-effectively as possible.

With the foregoing and other objects in view there is provided, in accordance with the invention, a semiconductor element, comprising at least a thermoelectric material and a first frame part which are connected to one another in a force-locking manner, and in which the first frame part forms an electric current conductor and is formed of a ferritic steel.

The semiconductor element therefore in this case constitutes the smallest structural unit and is already captively connected to the first frame part and in a force-locking manner. A force-locking manner means in this case, in particular, that mutual displacement is prevented as long as a counter force brought about by static friction is not exceeded.

A ferritic steel is understood to mean a crystallographic modification of iron which forms a body-centred cubic crystal lattice. The ferritic steel proposed in this case has, in particular, a good thermal conductivity and at the same time a low thermal expansion, besides a good electrical conductivity.

In particular, a diffusion barrier is additionally disposed between the semiconductor material and the first frame part, in such a way that alloy elements from the frame part do not diffuse into the semiconductor material and impair the efficacy thereof with regard to the conversion of thermal energy into electrical energy. The diffusion barrier is to be embodied, in particular, from nickel or molybdenum. Preferably, however, no additional diffusion barrier is required between the semiconductor material and the first frame part. At the same time, the first frame part provides an electric current conductor, in such a way that the first frame part of a semiconductor element can also be directly connected to adjacent semiconductor elements or the first frame parts thereof and an electric current generated by the thermoelectric module thus flows, in particular, exclusively through the frame parts and the semiconductor elements (and the diffusion barriers) of the thermoelectric module. In particular, the semiconductor element and the first frame part are connected to one another at least partly in a form-locking or even cohesively-connected manner. A form-locking connection means in this case, in particular, that a relative movement of the connection partners in at least one direction, preferably in any direction, is not possible since the connection partners are in the way of one another. Cohesively connected means in this case, in particular, that the connection partners are held together by atomic or molecular forces.

In particular, the following materials can be used as a thermoelectric material:
n-type: Bi₂Te₃; PbTe; Ba_{0.3}Co_{3.95}Ni_{0.05}Sb₁₂; Ba_{y}(Co,Ni)₄Sb₁₂; CoSb₃; Ba₈Ga₁₆Ge₃₀; La₂Te₃; SiGe; Mg₂(Si,Sn);
p-type: (Bi,Sb)₂TE₃; Zn₄Sb₃; TAGS; PbTe; SnTe; CeFe₄Sb₁₂; Yb₁₄MnSb₁₁; SiGe; Mg₂(Si,Sb).

In accordance with another preferred feature of the semiconductor element of the invention, the ferritic steel includes at least the following alloying constituents:
at most 0.025% by weight of carbon (C),
21 to 24% by weight of chromium (Cr),
0.7 to 1.5% by weight of molybdenum (Mo),
at most 1% by weight of niobium (Nb),
at most 78.3% by weight of iron (Fe).

In particular, the ferritic steel can contain further alloying constituents, but each of the latter do not exceed a proportion of 1% by weight, and preferably are in each case at most 0.2% by weight. In particular, provision is made for all further alloying constituents to make up overall at most 3% by weight, preferably even only at most 1% by weight.

The ferritic steel, in particular having the alloy composition indicated above, has, in particular, a thermal conduction of approximately 26 W/m° C. [watts/meter*degree Celsius] measured at 100° C. In particular, a coefficient of thermal expansion of approximately 10*10⁻⁶ (0.00001) per degree kelvin [1/K] is present in a range of 20° C. and 100° C. At the same time, the ferritic steel has very good corrosion resistance, so that a high durability of the properties of the first frame part can be ensured. By comparison with the materials usually used for electrically conductive bridges between the semiconductor elements, the ferritic steel also has a significant cost advantage.

One particularly preferred alloy composition of the ferritic steel is indicated below:
0.006% by weight of carbon (C),
22% by weight of chromium (Cr),
1.0% by weight of molybdenum (Mo),
0.3% by weight of niobium (Nb), and
remainder iron (Fe),
wherein “impurities” are present only with a proportion of at most 1% by weight.

In accordance with a further particularly advantageous feature of the semiconductor element of the invention, a second frame part for the semiconductor element is disposed on an element surface of the thermoelectric material that is situated opposite an element surface on which the first frame part is disposed. In this case, the thermoelectric material is embodied, in particular, in the manner of a cylinder, cube, bar and/or annulus segment, wherein the first frame part and the second frame part are disposed on mutually opposite element surfaces of the thermoelectric material. All explanations relating to the first frame part also apply, without restriction, to the second frame part, and vice-versa.

In accordance with an added advantageous feature of the semiconductor element of the invention, the thermoelectric material, the first frame part and the second frame part are ring-shaped, wherein the first frame part is disposed on an inner circumferential surface and the second frame part is disposed on an outer circumferential surface of the thermoelectric material. In particular, such a configuration makes it possible to produce a tubular thermoelectric module in which the semiconductor elements are disposed one behind another and are electrically connected to one another in each case alternately through first frame parts and second frame parts.

In accordance with an additional feature of the semiconductor element of the invention, at least the first frame part has two opposite surfaces spaced apart from one another, wherein one of the surfaces is a linking surface facing the thermoelectric material, the distance between the surfaces defines a thickness of the first frame part, and the thickness is 0.1 mm to 1 mm [millimeter], preferably 0.2 to 0.5 mm. In particular, the first frame parts and the second frame parts spaced apart from one another by the thermoelectric material are at a distance from one another of 1 to 5 mm [millimeters], that is to say that the material thickness of the thermoelectric material is 1 to 5 mm. The second frame part can be embodied in the same way, if appropriate.

In accordance with yet another advantageous feature of the semiconductor element of the invention, at least the first frame part has two opposite contact surfaces spaced apart from one another, the distance between which defines a first width. In this case, the first width is at least partly greater than a second width of the thermoelectric material, so that the first frame part projects at least at one side beyond the thermoelectric material. The contact surfaces mentioned herein serve, in particular, for making contact with semiconductor elements disposed adjacent one another, through the frame parts thereof. The extent of the first frame part with a first width and of the thermoelectric material with a second width is considered, in particular, in a parallel direction with respect to one another, in such a way that the definition that the first width is at least partly greater than the second width clarifies the fact that the first frame part projects beyond the thermoelectric material at least at one side of the thermoelectric material. Preferably, in this case, the first frame part is disposed flush with the thermoelectric material at least at one side. It is especially preferred for this (individual) projection to be provided only over a small part of the extent of the first frame part, in particular only over 30% or even only 20% of the extent (in the circumferential direction). The second frame part can be embodied in the same way, if appropriate.

Provision can also be made for at least the first frame part to additionally project relative to the thermoelectric material at least at one further side. Such a configuration is advantageous in particular when the first frame parts are connected through the contact surfaces, so that, in the case of welding, soldering or brazing or adhesively bonding together the contact surfaces of the semiconductor elements disposed alongside one another, damage or contamination of the thermoelectric material, whereby the efficacy with regard to the conversion of thermal energy into electrical energy might be impaired, does not occur. The second frame part can be embodied in the same way, if appropriate.

In accordance with yet another advantageous feature of the semiconductor element of the invention, at least the first frame part has a coating, which is disposed at least on the linking surface facing the thermoelectric material. The second frame part can be embodied in the same way, if appropriate. The coating includes, in particular, a solder or brazing material and/or a material for increasing the connection areas of thermoelectric material and first or second frame part. In this case the solder or brazing material, in particular, must additionally have the properties of a diffusion barrier since it is disposed between the thermoelectric material and the first or second frame part. By virtue of the coating, the connection between the first or second frame part and the thermoelectric material becomes possible or is embodied with the highest possible strength. Consequently, the thermally conductive contact-connection between the first or second frame part and the thermoelectric material can also be improved or ensured, in such a way that the efficacy of the semiconductor element or of the thermoelectric module having a multiplicity of semiconductor elements is ensured.

In accordance with yet a further advantageous feature of the semiconductor element of the invention, a coating used for this purpose in particular includes solder or brazing material.

Furthermore, it is proposed that at least the first frame part at least partly has, at least on the linking surface facing the thermoelectric material, a surface structure including at least one of the following elements:
groove,
shoulder,
elevation,
roughness Rz of at least 12 μm.

The surface structure results, in particular, in a form-locking connection of the thermoelectric material through the at least one element towards the first frame part. The element improves the connection between the thermoelectric material and the first frame part with regard to the connection strength. The second frame part can be embodied in the same way, if appropriate.

In this case a groove includes a depression within the first frame part, which differs from a shoulder to the effect that, in the case of a (circumferentially extending) shoulder, the depression extends as far as a contact surface, in such a way that the first frame part would be able to be pushed onto a thermoelectric material. The elevation indicated herein is, in contrast to the groove and the shoulder, a continuation of the frame part which extends into the thermoelectric material and thus makes a form-locking connection between the thermoelectric material and the first frame part possible.

The roughness Rz defined herein is usually determined according to German Industrial Standard DIN 4768, where in this case a value of at least 12 μm [micrometers], in particular at least 20 μm, is present, so that a large surface area for connecting the thermoelectric material and the first frame part is present.

With the objects of the invention in view, there is also provided a method for producing a semiconductor element, which comprises at least the following steps:
a) providing at least a first frame part;
b) placing a thermoelectric material on a linking surface of the first frame part; and
c) pressing at least the first frame part and the thermoelectric material together, in such a way that they both enter into a force-locking connection.

The method is suitable, in particular, for producing a semiconductor element described herein according to the invention.

The individual steps are regularly implemented in the order indicated herein, wherein, if appropriate, a plurality of semiconductor elements can be produced jointly. With regard to the method, it should be noted that in step a), if appropriate, a second frame part can also be provided, so that in step b) the thermoelectric material is then disposed between the linking surfaces of both frame parts and is then pressed together with the latter.

With the objects of the invention in view, there is furthermore provided a thermoelectric module, comprising at least semiconductor elements which are connected to one another by electrically conductive bridges in such a way that thermoelectric elements are formed, and at least one of the electrically conductive bridges includes a ferritic steel. With regard to the configurations of the ferritic steel, reference is made entirely to the above aspects concerning the first frame part.

In accordance with a concomitant preferred feature of the thermoelectric module of the invention, the electrically conductive bridge includes a ferritic steel having at least the following alloying constituents:
at most 0.025% by weight of carbon (C),
21 to 24% by weight of chromium (Cr),
0.7 to 1.5% by weight of molybdenum (Mo),
at most 1% by weight of niobium (Nb),
at most 78.3% by weight of iron (Fe).

In particular, the thermoelectric module includes at least two semiconductor elements according to the invention. In this case, the semiconductor elements in the thermoelectric module are disposed alongside one another in such a way that frame parts of adjacent semiconductor elements make contact with one another and are cohesively connected to one another at this contact-making location.

In accordance with a further advantageous configuration of the thermoelectric module, frame parts of adjacent semiconductor elements make contact with one another at a respective contact surface and are cohesively connected to one another at this contact-making location. In particular, such a configuration realizes a butt joint between the semiconductor elements disposed in an adjacent manner, in such a way that the semiconductor elements can be welded, soldered or brazed or adhesively bonded together in a particularly simple manner. Alternatively or additionally, frame parts of adjacent semiconductor elements make contact at a respective contact surface and are elastically connected to one another at this contact-making location, in particular by using a corresponding vulcanization and/or rubber coating.

Preferably, a cohesive connection of semiconductor elements disposed in an adjacent manner can be formed by welding, in particular by laser welding.

In particular, in the thermoelectric module, at least one first frame part is thermally conductively connected directly to a hot medium or at least one second frame part is thermally conductively connected to a cold medium only through an electrical insulation. Likewise, both features can be jointly provided.

In particular, hot medium is considered in this case to be the exhaust gas of an internal combustion engine which flows over a thermoelectric module. In particular, that surface of the thermoelectric module which faces the exhaust gas is formed at least by a plurality of first frame parts. The first frame parts are cohesively connected to one another in an electrically conductive manner among one another. Alternately, however, the semiconductor elements are also embodied in a manner electrically insulated from one another, in such a way that the electric current is conducted alternately from a hot side to a cold side through n-doped and p-doped semiconductor elements. The first frame parts produce an electric current path along the thermoelectric module and in this case form the outer surface of the thermoelectric module which is intended to enable heat to be transferred with the fewest possible losses from a hot medium to the semiconductor elements. Since at least the first frame parts thus form the housing of the thermoelectric module at the hot side, an electrical insulation of the electrically conductive first frame parts relative to the exhaust gas can be dispensed with in this case. As a result, the customary construction composed of housing, electrical insulation, electrically conductive current paths, diffusion barrier, thermoelectric material is significantly simplified. The semiconductor elements disposed adjacent one another can have, at their contact surfaces facing one another, in particular, electrical insulation elements which enable the thermoelectric module to be sealed relative to the exhaust gas and, on the other hand, electrically insulate the first frame parts from one another.

Correspondingly, second frame parts are also proposed, which, in particular, delimit the thermoelectric module relative to a cold medium. The cold medium in this case is a liquid, in particular. An electrical insulation should at the same time enable good heat conduction, in such a way that the efficiency of the thermoelectric module with regard to the conversion of thermal energy contained in the exhaust gas to electrical energy is not restricted. By way of example, a film which is provided as the electrical insulation can be applied to the corresponding surface of the thermoelectric module in a simple manner. Alternatively or additionally, a shrinkable sleeve can be provided as the electrical insulation, in particular on that side of the second frame parts which faces the cold medium. An electrical insulation can be applied on the frame parts on the outside and/or on the inside, in particular on the outside, preferably in those regions of the frame parts which form the outer surface of the thermoelectric module.

The semiconductor elements and the thermoelectric modules proposed herein are suitable, in particular, for thermoelectric generators which are used for motor vehicles and which are intended to convert the thermal energy of an exhaust gas of an internal combustion engine into electrical energy. The configurations described in connection with the ferritic steel for the first frame part can be applied, in particular, to the electrically conductive bridges of the thermoelectric module.

Other features which are considered as characteristic for the invention are set forth in the appended claims, noting that the features individually presented in the claims can be combined with one another in any technologically expedient manner and indicate further configurations of the invention.

Although the invention is illustrated and described herein as embodied in a semiconductor element for a thermoelectric module and a thermoelectric module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings. The description, in particular in connection with the figures, elucidates the invention further and mentions supplementary exemplary embodiments of the invention.

### BRIEF DESCRIPTION OF THE SEVERAL VIEWS OF THE DRAWING

FIG. 1 is a diagrammatic, axial-sectional view of a semiconductor element;

FIG. 2 is an axial-sectional view of a first frame part;

FIG. 3 is an axial-sectional view of a second frame part;

FIG. 4 is a longitudinal-sectional view of a thermoelectric module;

FIG. 5 is an axial-sectional view of a first configuration of semiconductor elements; and

FIG. 6 is an axial-sectional view of a second configuration of semiconductor elements.

### DETAILED DESCRIPTION OF THE INVENTION

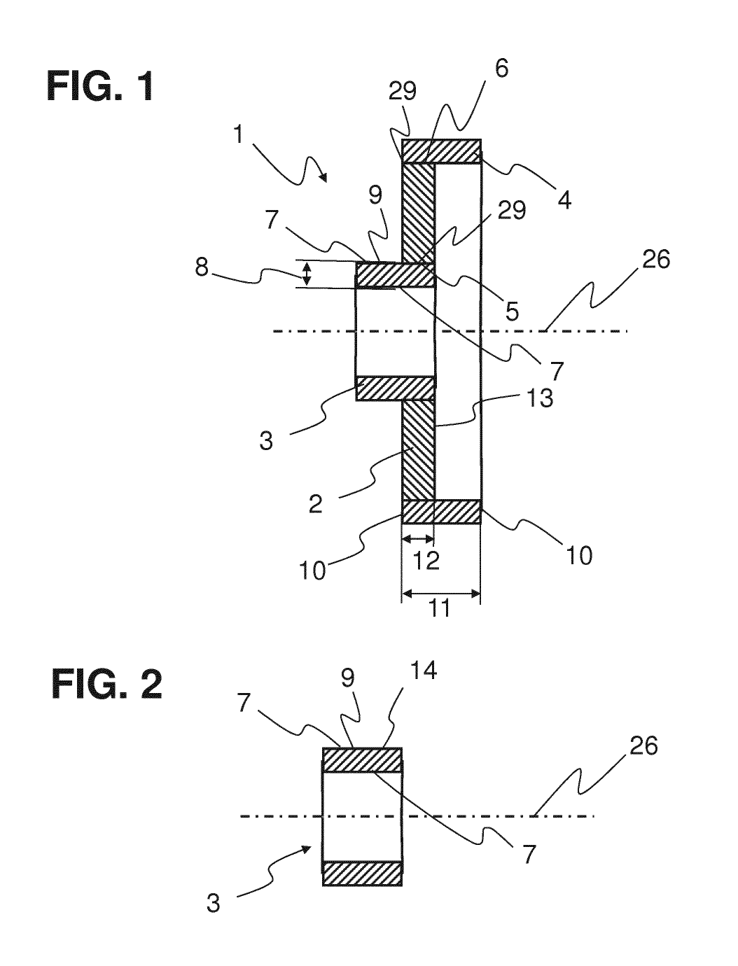

Referring now in detail to the figures of the drawing for explaining the invention and the technical field in more detail by showing particularly preferred structural variants to which the invention is not restricted, and first, particularly, to FIG. 1 thereof, there is seen a ring-shaped semiconductor element 1 with a thermoelectric material 2 and a first frame part 3 which is disposed on an inner circumferential surface 5 of the thermoelectric material 2. A second frame part 4 is disposed on an outer circumferential surface 6 of the thermoelectric material 2. Even though in this case the designation “first frame part” is used for the inner frame part and the designation “second frame part” is used for the outer frame part, such an assignment of terms is not mandatory for other embodiment variants of the invention.

The outer circumferential surface 6 is an element surface 29 of the thermoelectric material 2 which is situated opposite an element surface 29 of the thermoelectric material 2 at which the latter is connected to the first frame part 3. The first frame part 3 has two mutually opposite surfaces 7 and a linking surface 9 is formed at the surface 7 situated opposite the thermoelectric material 2. A thickness 8 of the first frame part 3 is formed between the mutually opposite surfaces 7. The second frame part 4 has two mutually opposite contact surfaces 10, between which a first width 11 of the second frame part 4 extends. In a corresponding parallel direction, the thermoelectric material 2 has a second width 12, which in this case is less than the first width 11. Correspondingly, the second frame part 4 projects in the direction of a central axis 26 beyond the thermoelectric material 2 at a side 13 of the thermoelectric material 2. A corresponding projection beyond the thermoelectric material 2 is also formed at the first frame part 3 in the direction of the central axis 26 in a direction opposite to the second frame part 4.

FIG. 2 shows a ring-shaped first frame part 3 having two mutually opposite surfaces 7, in which the outer surface 7 forms a linking surface 9 for linking the first frame part 3 to the thermoelectric material. In this case, a coating 14 is provided for increasing the connection strength between first frame part 3 and thermoelectric material 2. The coating is applied on the linking surface 9.

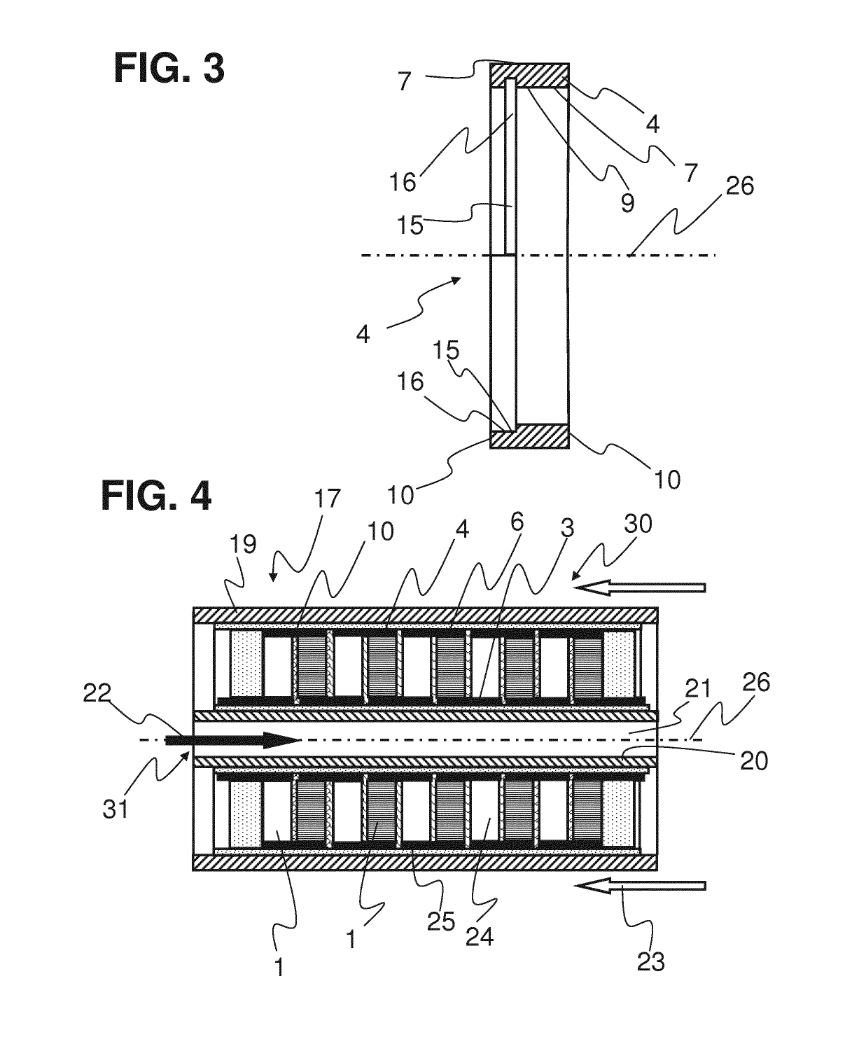

FIG. 3 shows a second frame part 4 having corresponding mutually opposite surfaces 7, wherein in this case the inner circumferential surface of the ring-shaped second frame part 4 has the linking surface 9 for linking the second frame part 4 to the thermoelectric material. An element 16 acting as a surface structure 15 is illustrated on the linking surface 9 in the upper part of FIG. 3. The element 16 is embodied in this case as a groove. The thermoelectric material extends into the groove, in such a way that it is fixed within the ring-shaped second frame part 4 at least in the direction of the central axis 26. In this case, the thermoelectric material can extend in the direction of the central axis 26 on both sides of the groove within the second frame part 4. The element 16 is a shoulder which is illustrated as a surface structure 15 in the lower half of FIG. 3. The element allows the thermoelectric material to be fixed at least in one direction of the central axis 26. The thermoelectric material is disposed between the ring-shaped linking surface 9 and the lateral contact surfaces 10.

FIG. 4 shows a thermoelectric module 17 including a multiplicity of semiconductor elements 1. The semiconductor elements 1 are disposed in a ring-shaped manner around an inner tube 20 and are enclosed by an outer tube 19 on an outer circumferential surface 6. The inner tube 20 forms a channel 21, through which a hot medium 22 flows along the central axis 26. A cold medium 23 flows over the thermoelectric module 17 on the outer circumferential surface of the outer tube 19. As a result, a temperature potential forms between the outer tube 19 and the inner tube 20, in such a way that, by using the semiconductor elements 1 which are respectively electrically connected to one another alternately on the cold side 30 and the hot side 31, an electric current is able to be generated through the thermoelectric module 17 due to the thermoelectric effect. Respective second frame parts 4 and first frame parts 3 are electrically conductively connected to one another at the contact surfaces 10. The frame parts 3, 4 can also be designated as electrically conductive bridges 25 through which the semiconductor elements are connected to form thermoelectric elements 24.

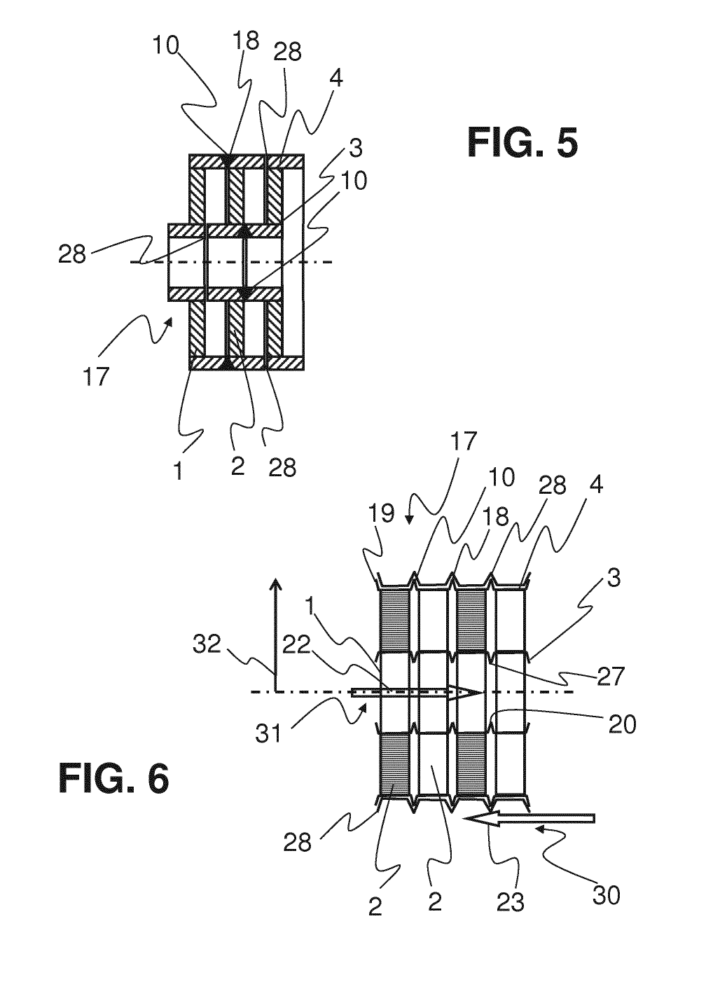

FIG. 5 shows a first configuration of semiconductor elements 1 to form a thermoelectric module 17. The semiconductor elements 1, which are constructed in this case in accordance with FIG. 1, are alternately cohesively connected to one another through respective first frame parts 3 and second frame parts 4 at contact surfaces 10 forming contact-making locations 18. Correspondingly, electrical insulations 28 are alternately provided between respectively adjacent first frame parts 3 and respectively adjacent second frame parts 4, with the electrical insulations producing a corresponding current path through the thermoelectric module 17.

FIG. 6 shows a second configuration of semiconductor elements 1 to form a thermoelectric module 17. In this case, n-doped and p-doped thermoelectric materials 2 are respectively electrically conductively connected to one another through first frame parts 3 and second frame parts 4 and through contact surfaces 10 forming contact-making locations 18 or are insulated from one another at the contact surfaces 10. In this case a cold medium 23 flows over the thermoelectric module 17 directly on the outer surface of the thermoelectric module 17 that is formed by the second frame parts 4. The second frame parts 4, which are embodied in a manner extending circumferentially in a ring-shaped manner and protrude outwards in a radial direction, are alternately electrically conductively connected to one another or connected to one another in an electrically insulated manner at contact surfaces 10 and thus form a continuous outer tube 19. Correspondingly, on the inner side of the thermoelectric module 17, the first frame parts 3 form the inner tube 20, through which a hot medium 22 flows. Since the hot medium 22 is regularly an exhaust gas, an electrical insulation of the first frame parts 3 relative to the exhaust gas can be dispensed with in this case on the hot side 31. When an electrically conductive cold medium 23 is used on the cold side 30, an electrical insulation 28 is required, which is applied on the outside on the second frame parts 4. The insulation can be embodied, for example, as a shrinkable sleeve. The frame parts 3, 4 protruding outwards and inwards form compensation elements 27 which make a thermal expansion of the thermoelectric module 17 possible in the direction of the central axis 26. At the same time, a relative displacement of the semiconductor elements 1 with respect to one another in a radial direction 32 is also made possible.

The present invention has at least partly solved the problems outlined with regard to the prior art. In particular, a semiconductor element has been specified which is suitable for diverse cases of use and which enables a thermoelectric module to be constructed as simply and cost-effectively as possible. In this case, the ferritic material mentioned herein for the first frame part can also very generally be used as an electrically conductive bridge between semiconductor elements in thermoelectric modules, in such a way that this material can also be employed independently of the semiconductor material.

1. A semiconductor element, comprising:
a thermoelectric material; and
a first frame part forming an electric current conductor and being formed of a ferritic steel;
said thermoelectric material and said first frame part being interconnected in a force-locking manner.

2. The semiconductor element according to claim 1, wherein said ferritic steel includes at least the following alloying constituents:
at most 0.025% by weight of carbon,
21 to 24% by weight of chromium,
0.7 to 1.5% by weight of molybdenum,
at most 1% by weight of niobium, and
at most 78.3% by weight of iron.

3. The semiconductor element according to claim 1, wherein:
said thermoelectric material has an element surface on which said first frame part is disposed and an element surface disposed opposite said element surface on which said first frame part is disposed; and
a second frame part is disposed on said element surface disposed opposite said element surface on which said first frame part is disposed.

4. The semiconductor element according to claim 3, wherein:
said thermoelectric material, said first frame part and said second frame part are ring-shaped;
said thermoelectric material has inner and outer circumferential surfaces;
said first frame part is disposed on said inner circumferential surface; and
said second frame part is disposed on said outer circumferential surface.

5. The semiconductor element according to claim 1, wherein:
at least said first frame part has two opposite surfaces spaced apart from one another by a distance defining a thickness of said first frame part of between 0.1 mm and 1 mm; and
one of said opposite surfaces is a linking surface facing said thermoelectric material.

6. The semiconductor element according to claim 1, wherein:
at least said first frame part has two opposite contact surfaces spaced apart from one another by a distance defining a first width;
said thermoelectric material has a second width; and
said first width is at least partly greater than said second width causing said first frame part to project at least at one side of said thermoelectric material.

7. The semiconductor element according to claim 1, wherein said first frame part has a linking surface facing said thermoelectric material, and at least said first frame part has a coating disposed at least on said linking surface.

8. The semiconductor element according to claim 6, wherein said coating includes a solder or brazing material.

9. A thermoelectric module, comprising:
semiconductor elements; and
electrically conductive bridges interconnecting said semiconductor elements to form thermoelectric elements;
at least one of said electrically conductive bridges including a ferritic steel.

10. The thermoelectric module according to claim 9, wherein said ferritic steel of said at least one electrically conductive bridge has at least the following alloying constituents:
at most 0.025% by weight of carbon,
21 to 24% by weight of chromium,
0.7 to 1.5% by weight of molybdenum,
at most 1% by weight of niobium, and
at most 78.3% by weight of iron.
